(19) United States
(12) Patent Application Publication
(10) Pub. No.: US 2009/0026546 A1
(43) Pub. Date: Jan. 29, 2009

(54) SEMICONDUCTOR DEVICE

(75) Inventors: Masaki SHIMADA, Tokyo (JP); Toshio YAMADA, Tokyo (JP); Hisanori ITO, Tokyo (JP); Katsuhiro KOGA, Kodaira (JP)

Correspondence Address: MILES & STOCKBRIDGE PC, 1751 PINNACLE DRIVE, SUITE 500, MCLEAN, VA, 22102-3833, US

(73) Assignee: RENESAS TECHNOLOGY CORP.

(21) Appl. No.: 12/178,716

(22) Filed: Jul. 24, 2008

(30) Foreign Application Priority Data
Jul. 25, 2007 (JP) 2007-193280

(51) Int. Cl. H01L 27/088

(52) U.S. Cl. 257/368; 257/E27.06

(57) ABSTRACT

To provide a technique capable of achieving high integration of semiconductor devices. A standard cell is provided in an n-type well, and includes a p⁺-type diffusion layer and n⁺-type diffusion layer covered with a metal silicide film. The p⁺-type diffusion layer constitutes a source/drain of an MIS transistor, and the n⁺-type diffusion layer constitutes a tap. The p⁺-type diffusion layer is electrically coupled to a wiring layer via a contact, and the n⁺-type diffusion layer is electrically coupled to a wiring layer via a contact. Moreover, the p⁺-type diffusion layer is in contact with the n⁺-type diffusion layer. A power supply potential supplied to the source node of the MIS transistor is provided using two layers, i.e., the diffusion layer and the wiring layer.

### CROSS-REFERENCE TO RELATED APPLICATION

The present application claims priority from Japanese patent application No. 2007-193280 filed on Jul. 25, 2007, the content of which is hereby incorporated by reference into this application.

### BACKGROUND OF THE INVENTION

The present invention relates to semiconductor devices, and in particular, relates to a technique effective when applied to standard cell type semiconductor devices.

For a need for miniaturization of a semiconductor device, a reduction in size of a semiconductor chip is performed, for example. Thus, miniaturization of a transistor formed in a semiconductor chip is also attempted. This miniaturization allows the transistor characteristics to be improved while allowing for a reduction in the chip size. However, since the technique required for the miniaturization of wirings and contacts is less advanced relative to the technique required for the miniaturization of transistors, innovative ideas are required in the arrangement of the wirings and contacts. Note that a contact in the present application refers to a contact for coupling a well or a substrate to a power supply potential or a reference potential (e.g., GND).

For example, as a transistor becomes smaller due to miniaturization and the area occupied by wirings and contacts becomes relatively large, within a predetermined area where a standard cell is formed it is impossible to arrange the wirings and contacts in an unoccupied area even in an area over the standard cell. For this reason, it is contemplated that the size of the area where a standard cell is formed is increased or the size of the diffusion layer constituting the transistor is reduced.

Japanese Unexamined Patent Publication No. 2006-287257 (Patent Document 1) discloses a technique for achieving further reduction in size of a standard cell and improving the degree of integration. Specifically, this standard cell includes a substrate region (diffusion layer) formed beyond the border line between a cell and a tap for supplying an electric potential to the cell. This substrate region is shared and used by either one of adjoining cells. In the substrate region, contacts for supplying a predetermined electric potential to the substrate region are formed at uneven intervals. These contacts are arranged and formed near the adjoining cell from the center of the width of the substrate region. Namely, the diffusion layer for forming the substrate region of a portion where these contacts are formed is arranged extending to the inner side of the cell.

### SUMMARY OF THE INVENTION

The present inventors have been studying a standard cell type semiconductor device. FIG. 11 and FIG. 12 illustrate plan views (layout patterns) of a principal part of a semiconductor device including a standard cell which the present inventors studied, the standard cell including an MIS transistor. Reference numeral 101 represents a diffusion layer constituting a tap used for a power supply potential, 101a; an extension part projecting from the diffusion layer 101, 102; a diffusion layer constituting a tap used for a reference potential, 102a; an extension part projecting from the diffusion layer 102, 103 and 103a; contacts, 104; a diffusion layer constituting an MIS transistor, and 105; a gate (gate electrode) of the MIS transistor. In addition, reference symbols X and Y in FIG. 11 and FIG. 12 denote the width in the horizontal direction and the width in the vertical direction in the view, respectively, which indicate a predetermined area where a standard cell is formed, while reference symbol Z denotes the width (in the vertical direction in the view) of the diffusion layers 101, 102 constituting a tap.

FIG. 11 illustrates a case where there is a minimum alignment margin in the contact 103, while FIG. 12 illustrates a case where there is enough alignment margin in the contact 103. Moreover, FIG. 11 and FIG. 12 illustrate layout patterns in which the diffusion layer 102 is used as a common layer. A number of contacts 103 are provided along the diffusion layers 101, 102 constituting the taps. This is for preventing a voltage drop in supplying a voltage to each cell. Among these contacts 103, a contact 103a is provided so as to overlap with extension parts 101a, 102a.

As illustrated in FIG. 11 and FIG. 12, in the layout pattern which the present inventors studied, as in Patent Document 1 described above, the contact 103 is provided overlapping from the diffusion layer 101 constituting the tap used for the power supply potential to the projecting extension part 101a so that the contact 103 is arranged and formed from the center of the width Z of the diffusion layers 101, 102 to near an inner side of the cell. Moreover, the contact 103a is provided overlapping from the diffusion layer 102 constituting the tap used for the reference potential to the projecting extension part 102a.

Inside the standard cell, since the location of a terminal of a cell, the size of the cell, and the like are not necessarily identical, various patterns may be employed for the arrangement of the extension parts 101a, 102a and the arrangement of the contact 103 that overlaps with the extension parts 101a, 102a. Here, as in a portion enclosed by a circle in FIG. 11, when the extension part 102a is arranged in the vertical direction of the diffusion layer 102 in the view, in FIG. 11 the contacts 103a may be overlappingly arranged relative to each other since the alignment margin of the contacts 103, 103a is the minimum. Moreover, when there is not enough alignment margin in the contact 103, if a shift in the position of the contact 103 occurs, apart of the contact 103 may deviate from the surface of the diffusion layer 102, causing a non-conducting problem.

On the other hand, as illustrated in FIG. 12, when there is enough alignment margin in the contacts 103, 103a, the contact between the contacts 103a or the non-conduction of the contact 103 can be avoided. However, the width Z of the diffusion layers 101, 102 needs to be increased in order to increase the alignment margin of the contacts 103, 103a. For this reason, if the chip size of a semiconductor chip in which standard cells are formed is made identical and the same number of the standard cells are provided, the width Y of the region in which the standard cells are formed will be narrowed and the region in which the standard cells are formed will be smaller. Namely, by the amount that the area of the diffusion layers 101, 102 constituting the tap increases, a channel width C2 shown in FIG. 12 will be narrower relative to a channel width C1 of the MIS transistor shown in FIG. 11 and the current obtained in the MIS transistor will decrease.

Moreover, on the other hand, according to the study of the present inventor, the extension parts 101a, 102a and the diffusion layers 101, 102 are regions doped with impurities having mutually different conductivity types. The present inventor has found that although a silicide film is formed above the extension parts 101a, 102a and above the diffusion layers 101, 102, in a boundary part between such regions having mutually different conductivity types the silicide film is likely to condense to cause a disconnection problem.

It is an object of the present invention to provide a technique capable of achieving high integration of semiconductor devices.

It is another object of the present invention to provide a technique capable of eliminating a conduction failure of standard cell type semiconductor devices and reducing the layout size of a standard cell.

The above and other objects and novel features of the present invention will be apparent from the description and the accompanying drawings of this specification.

A summary of a representative invention among the present inventions disclosed in the present application is described briefly as follows.

A semiconductor device shown in an embodiment of the present invention includes a standard cell. The semiconductor device including the standard cell comprises: a semiconductor substrate; a first conductive type well provided in a major side of the semiconductor substrate; a first diffusion layer of a second conductive type opposite to the first conductive type provided in the well; and a second diffusion layer of the first conductive type provided in the well. This semiconductor device further comprises: a wiring layer provided in an upper layer of the semiconductor substrate and supplying an electric potential to the standard cell; a first contact provided above the first diffusion layer and electrically coupled to the wiring layer; and a second contact provided above the second diffusion layer and electrically coupled to the wiring layer. Here, the first diffusion layer constitutes the standard cell, the second diffusion layer forms a tap for supplying an electric potential of the well, a part of the first diffusion layer is in contact with the second diffusion layer, and the first contact is provided above the part of the diffusion layer.

The effect obtained by the representative one among the present inventions disclosed in the present application will be described briefly as follows.

The present invention makes it possible to achieve high integration of semiconductor devices.

### BRIEF DESCRIPTION OF THE DRAWINGS

FIG. 1 is a plan view of a principal part schematically showing a semiconductor device in an Embodiment 1 of the present invention.

FIG. 2 is a cross sectional view along an X-X′ line of FIG. 1.

FIG. 3 is a plan view of a principal part schematically showing a semiconductor device which the present inventors studied.

FIG. 4 is a view for illustrating an effect of the present invention, showing a layout pattern of the Embodiment 1 of the present invention.

FIG. 5 is a view for illustrating an effect of the present invention, showing a layout pattern which the present inventors studied.

FIG. 6 is a plan view of a principal part schematically showing a semiconductor device in an Embodiment 2 of the present invention.

FIG. 7 is a plan view of a principal part schematically showing a semiconductor device in an Embodiment 3 of the present invention.

FIG. 8 is a cross sectional view along a Y-Y′ line of FIG. 7.

FIG. 9 is a circuit diagram of a semiconductor device in an Embodiment 4 of the present invention.

FIG. 10 is a plan view of a principal part schematically showing the semiconductor device in the Embodiment 4 of the present invention.

FIG. 11 is a plan view of a principal part schematically showing a semiconductor device which the present inventors studied.

FIG. 12 is a plan view of a principal part schematically showing a semiconductor device which the present inventors studied.

### DETAILED DESCRIPTION OF THE PREFERRED EMBODIMENTS

Hereinafter, embodiments of the present invention will be described in detail in accordance with the accompanying drawings. Note that throughout the accompanying drawings for illustrating the embodiments, the same member having the same function is given the same reference numeral to omit the duplicated description. Moreover, even in a plan view, hatching may be used for ease of viewability.

### Embodiment 1

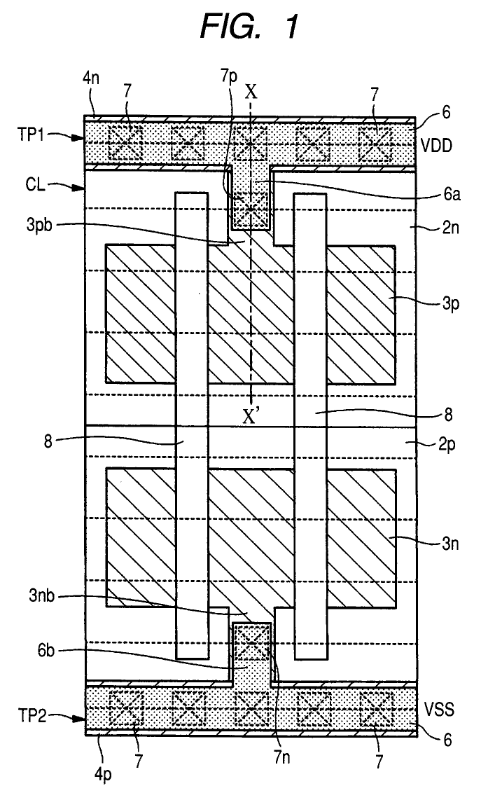

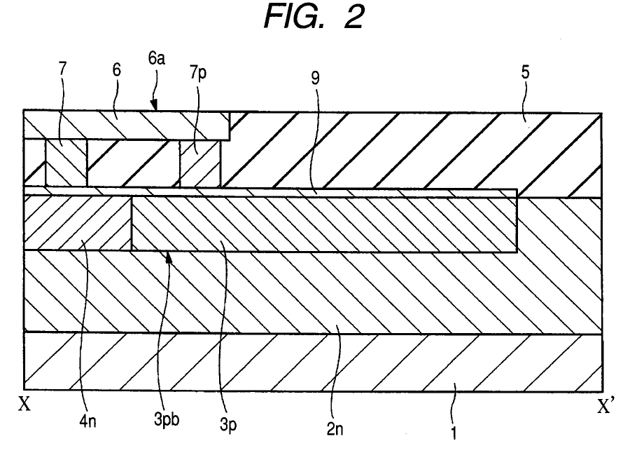

FIG. 1 is a plan view (layout pattern) of a principal part schematically showing an LSI (semiconductor device) in Embodiment 1 of the present invention, and FIG. 2 is a cross sectional view along an X-X′ line of FIG. 1. For example, on a major side (surface for forming elements) of a semiconductor substrate (hereinafter, referred to as a substrate) 1 composed of an n⁻-type single crystal silicon, a standard cell (logic circuit cell) CL and taps TP1, TP2 are laid out. The standard cell CL is configured using an MIS (Metal Insulator Semiconductor) transistor as a semiconductor element. Note that the MIS transistor, and a contact and a wiring layer thereabove can be formed using a well-known manufacturing method.

In the major side of the substrate 1 in which the standard cell CL and the taps TP1, TP2 are formed, an n-type well 2n and a p-type well 2p comprising n-type and p-type impurities, respectively, which are introduced using a photolithography technique and an ion implantation technique, are formed. An electric potential of a power supply VDD is supplied to the n-type well 2n from the tap TP1, and an electric potential of a power supply VSS is supplied to the p-type well 2p from the tap TP2. Note that if the electric potential of the power supply VDD is a power supply potential, then the electric potential of the power supply VSS is a reference potential.

In the n-type well 2n, a p⁺-type diffusion layer (p⁺-type semiconductor region) 3p constituting a source/drain of a p-channel type MIS transistor is formed. Moreover, in the p-type well 2p, an n⁺ type diffusion layer (n⁺-type semiconductor region) 3n constituting a source/drain of an n-channel type MIS transistor is formed. These p⁺-type diffusion layer 3p and n⁺-type diffusion layer 3n comprise p-type and n-type impurities which are introduced using a photolithography technique and an ion implantation technique.

Moreover, although illustration is omitted for simplicity of description in the present embodiment, the source/drain of the p-channel type MIS transistor comprises the above-described p⁺-type diffusion layer 3p and a p⁻-type semiconductor region having a lower impurity concentration than the p⁺-type diffusion layer 3p. The p⁻-type semiconductor region is formed by ion implantation with a gate (gate electrode) 8 being as a mask. Subsequently, a side wall spacer comprising an insulation layer, such as a silicon oxide film, is formed on a side wall of the gate 8, and then the p⁺-type diffusion layer 3p is formed by ion implanting with the side wall spacer being as a mask. Similarly, the source/drain of the n-channel type MIS transistor comprises the above-described n⁺-type diffusion layer 3n and an n⁻-type semiconductor region having a lower impurity concentration than the n⁺-type diffusion layer 3n. The n⁻-type semiconductor region is formed by ion implantation with the gate 8 being as a mask. Subsequently, a side wall spacer comprising an insulation layer, such as a silicon oxide film, is formed on a side wall of the gate 8, and then the n⁺-type diffusion layer 3n is formed by ion implantation with the side wall spacer being as a mask.

Moreover, in the n-type well 2n, an n⁺-type diffusion layer (n⁺-type semiconductor region) 4n is formed. Moreover, in the p-type well 2p, a p⁺ type diffusion layer (p⁺-type semiconductor region) 4p is formed. These n⁺-type diffusion layer 4n and p⁺-type diffusion layer 4p comprise n-type and p-type impurities, respectively, which are introduced using a photolithography technique and an ion implantation technique, and these layers serve as a lead layer of the tap TP1 and the tap TP2, respectively. Moreover, these n⁺-type diffusion layer 4n and p⁺-type diffusion layer 4p are formed in the same processes as those of the n⁺-type diffusion layer 3n and p⁺-type diffusion layer 3p, respectively.

The n⁺-type diffusion layer 4n constitutes the tap TP1 and is coupled to the power supply VDD of a wiring layer 6 via a contact 7, and the electric potential of the n-type well 2n is fixed to the power supply VDD (power supply potential). Moreover, the p⁺-type diffusion layer (p⁺-type semiconductor region) 4p constitutes the tap TP2 and is coupled to the power supply VSS of the wiring layer 6 via the contact 7, and the electric potential of the p-type well 2p is fixed to the power supply VSS (reference potential).

The gate 8 of the MIS transistor comprises a conductive polysilicon film, for example, and is formed via a gate insulation film (not illustrated) above the n-type well 2n and the p-type well 2p. Each of the two gates 8 constitutes a common gate shared by the p-channel type MIS transistor in the n-type well 2n and the n-channel type MIS transistor in the p-type well 2p. Moreover, p-type impurities are introduced into the gate 8 above the n-type well 2n, and n-type impurities are introduced into the gate 8 above the p-type well 2p. Note that a CMIS inverter is constituted by coupling the drain of the p-channel type MIS transistor in the n-type well 2n and the drain of the n-channel type MIS transistor in the p-type well 2p to each other.

As shown in FIG. 1, in the region for forming the standard cell CL, a part of the p⁺-type diffusion layer 3p having a different conductivity type is arranged so as to contact the n⁺-type diffusion layer 4n. The p⁺-type diffusion layer 3p constituting the source/drain of the MIS transistor has a substantially rectangular plane shape and a part thereof projects to contact the n⁺-type diffusion layer 4n. Moreover, in the region for forming the standard cell CL, a part of the n⁺-type diffusion layer 3n having a different conductivity type is arranged so as to contact the p⁺-type diffusion layer 4p. The n⁺-type diffusion layer 3n constituting the source/drain of the MIS transistor has a substantially rectangular plane shape and a part thereof projects to contact the p⁺-type diffusion layer 4p.

Hereinafter, the projection part of the diffusion layer constituting the source/drain is referred to as a BD (Butting Diffusion) part, and in FIG. 1 the projection part of the p⁺-type diffusion layer 3p is denoted as a BD part 3pb and the projection part of the n⁺ type diffusion layer 3n is denoted as a BD part 3nb. The BD part 3pb and the BD part 3nb can be considered as a part of the p⁺-type diffusion layer 3p and a part of the n⁺-type diffusion layer 3n, respectively, and can be considered as a part of the source of the MIS transistor. Moreover, the BD part 3pb and the BD part 3nb are provided in the region for forming the standard cell CL.

As shown in FIG. 2, a metal silicide film 9 is formed over the n⁺-type diffusion layer 4n and the p⁺-type diffusion layer 3p using a silicide technique. Similarly, also over the n⁺-type diffusion layer 3n and the p⁺-type diffusion layer 4p, the metal silicide film 9 is formed using the silicide technique. In this Embodiment 1, cobalt (Co) is used as the metal for forming the metal silicide film 9, and the metal silicide film 9 comprises a cobalt silicide film (CoSi₂). Moreover, as the other materials for the metal silicide film 9, a titanium silicide film (TiSi₂) and a nickel silicide film (NiSi₂) can be enumerated.

In this way, by providing the metal silicide film 9 over the p⁺-type diffusion layer 3p and the n⁺-type diffusion layer 3n constituting the source/drain of the MIS transistor and over the n⁺-type diffusion layer 4n and the p⁺-type diffusion layer 4p constituting the taps TP1, TP2, the p⁺-type diffusion layer 3p and the n⁺-type diffusion layer 4n are electrically coupled (short-circuited) to each other and the n⁺-type diffusion layer 3n and the p⁺-type diffusion layer 4p are electrically coupled (short-circuited) to each other.

However, during the manufacturing processes or when in use after the manufacturing, the metal silicide film 9 may be disconnected at a boundary between the p⁺-type diffusion layer 3p and the n⁺-type diffusion layer 4n and at a boundary between the n⁺-type diffusion layer 3n and the p⁺-type diffusion layer 4p. Similarly, the p⁺-type diffusion layer 3p and the n⁺-type diffusion layer 4n as well as the n⁺-type diffusion layer 3n and the p⁺-type diffusion layer 4p may not be electrically coupled to each other.

Then, other than the electric potential supply via the metal silicide film 9, the power supply potential is reliably supplied to the p⁺ type diffusion layer 3p serving as the source of the p-channel type MIS transistor via a wiring layer 6a and contacts 7, 7p that are coupled to the wiring layer 6 of the power supply VDD. Moreover, the reference potential is reliably supplied to the n⁺-type diffusion layer 3n serving as the source of the n-channel type MIS transistor via a wiring layer 6b and contacts 7, 7n that are coupled to the wiring layer 6 of the power supply VSS. The contacts 7, 7p, and 7n are formed by embedding a conductive material into a hole formed in an interlayer insulating film 5.

Namely, the contact 7p is formed above the BD part 3pb to electrically couple the wiring layer 6a and the p⁺-type diffusion layer 3p to each other. Moreover, the contact 7n is formed above the BD part 3nb to electrically couple the wiring layer 6b and the n⁺-type diffusion layer 3n to each other. Note that the contacts 7p, 7n are provided above the BD parts 3pb, 3nb while the contact 7 is provided above the taps TP1, TP2.

In this way, in this Embodiment 1, within the standard cell provided on an LSI, the power supply potential supplied to the source node of the MIS transistor is provided using two layers, i.e., the diffusion layer (metal silicide film) and the wiring layer. This can eliminate the conduction failure in the standard cell type semiconductor devices. Note that, as described later, the layout size can be reduced further than in a configuration in which the electric power is supplied only through the wiring layer.

Accordingly, the semiconductor device in this Embodiment 1 is an LSI including a standard cell CL, and comprises: the substrate 1; the n-type well 2n and the p-type well 2p provided in the major side of the substrate 1; the p⁺-type diffusion layer 3p and the n⁺-type diffusion layer 3n provided in the n-type well 2n and the p-type well 2p, respectively; and the n⁺-type diffusion layer 4n and the p⁺-type diffusion layer 4p provided in the n-type well 2n and the p-type well 2p, respectively. This semiconductor device further comprises: the wiring layer 6 provided in an upper layer of the substrate 1 and supplying an electric potential to the standard cell CL; the contacts 7p, 7n provided above the p⁺-type diffusion layer 3p and the n⁺-type diffusion layer 3n and electrically coupled to the wiring layer 6; and the contact 7 provided above the n⁺-type diffusion layer 4n and the p⁺-type diffusion layer 4p and electrically coupled to the wiring layer 6. Here, these p⁺-type diffusion layer 3p and n⁺-type diffusion layer 3n constitute the standard cell CL, the n⁺-type diffusion layer 4n and the p⁺-type diffusion layer 4p constitute the taps TP1, TP2 for supplying the electric potentials of the n-type well 2n and the p-type well 2p, respectively, a part of the p⁺-type diffusion layer 3p and a part of the n⁺-type diffusion layer 3n (BD parts 3pb, 3nb) are in contact with the n⁺-type diffusion layer 4n and the p⁺-type diffusion layer 4p, respectively, and the contacts 7a, 7b are provided above the BD parts 3pb, 3nb, respectively.

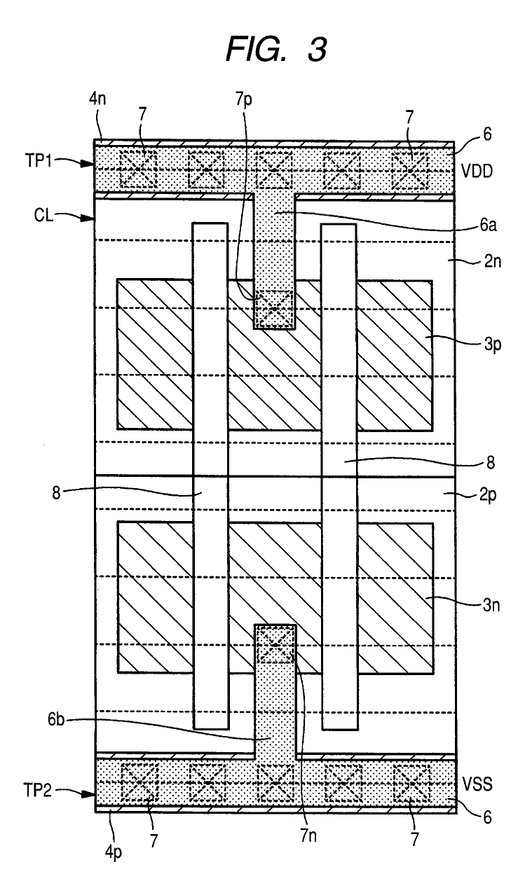

Here, a layout of the standard cell which the present inventors studied is shown in FIG. 3. In FIG. 3, the BD parts 3nb, 3pb illustrated in FIG. 1 are not laid out. For this reason, the contact 7p is provided above the p⁺-type diffusion layer 3p to electrically couple the wiring layer 6a and the p⁺-type diffusion layer 3p to each other. Moreover, the contact 7n is provided above the n⁺-type diffusion layer 3n to electrically couple the wiring layer 6b and the n⁺-type diffusion layer 3n to each other. Accordingly, the electric potential of the power supply VDD will be supplied to the source of the p-channel type MIS transistor only through the wiring layer 6a. Moreover, the electric potential of the power supply VSS will be supplied to the source of the n-channel type MIS transistor only through the wiring layer 6b.

In contrast thereto, in the semiconductor device of the present invention, not only the wiring layers 6a, 6b but the BD parts 3pb, 3nb are provided to supply, via the metal silicide film 9 thereover, the electric potential of the power supply VDD to the source of the p-channel type MIS transistor and also the electric potential of the power supply VSS to the source of the n-channel type MIS transistor.

Furthermore, in the semiconductor device of the present invention, the contacts 7p, 7b are provided above the BD parts 3pb, 3nb that are not provided in the studied layout. For this reason, in the studied layout, the wiring layers 6a, 6b for supplying the electric potentials need to be provided over the p⁺-type diffusion layer 3p and the n⁺-type diffusion layer 3n, while in the layout of the present invention, the wiring layers 6a, 6b are provided over the BD parts 3pb, 3nb, so that it is not necessary to provide these wiring layers over the p⁺-type diffusion layer 3p and the n⁺-type diffusion layer 3n. Accordingly, in the present invention, wirings other than the wiring layers 6a, 6b can be provided over the p⁺-type diffusion layer 3p and the n⁺-type diffusion layer 3n within the cell. In other words, since the wirings can be effectively provided within the cell, the layout size can be reduced.

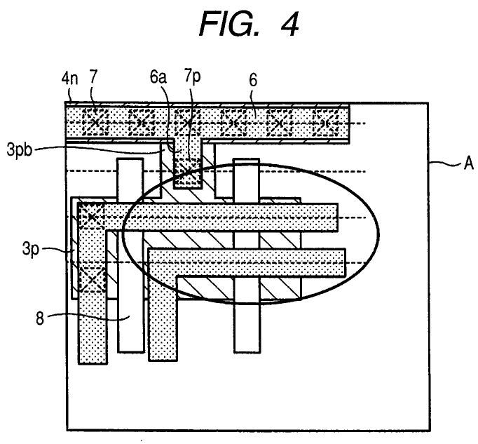

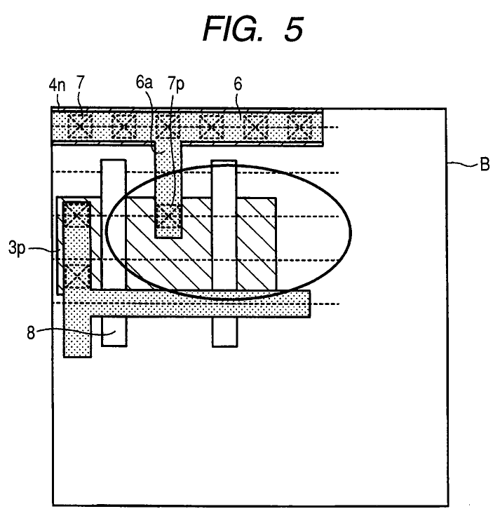

FIG. 4 and FIG. 5 are views for illustrating the effect of the present invention, wherein FIG. 4 illustrates the layout pattern of this Embodiment 1 and FIG. 5 illustrates the studied layout pattern described above. Note that reference symbol A in FIG. 4 represents a region in which the standard cell of this Embodiment 1 is formed, while reference symbol B of FIG. 5 represents a region in which the studied standard cell is formed. Moreover, dotted lines in the horizontal direction in FIG. 4 and FIG. 5 indicate that if the wiring layer 6 is provided, then the center of the wiring layer 6 will lie above the dotted line.

As shown in FIG. 4, in the layout pattern of this Embodiment 1, the wiring layer 6 is provided within the region of a portion enclosed by a circle and is effectively used in the cell forming region A. On the other hand, as shown in FIG. 5, in the layout pattern which the present inventors studied, the wiring layer 6 is not provided within the region of a portion enclosed by a circle. This is because in order to supply the electric potential to the p⁺-type diffusion layer 3p, the contact 7p is provided above the p⁺-type diffusion layer 3p and the wiring layer 6a is provided above this contact 7p, so that other wiring layer 6 cannot be provided.

Accordingly, when the layout pattern of this Embodiment 1 is compared with the studied layout pattern, the cell forming region A can be made smaller than the cell forming region B. Moreover, by reducing the area of the cell forming region A, higher integration of the semiconductor devices can be achieved.

### Embodiment 2

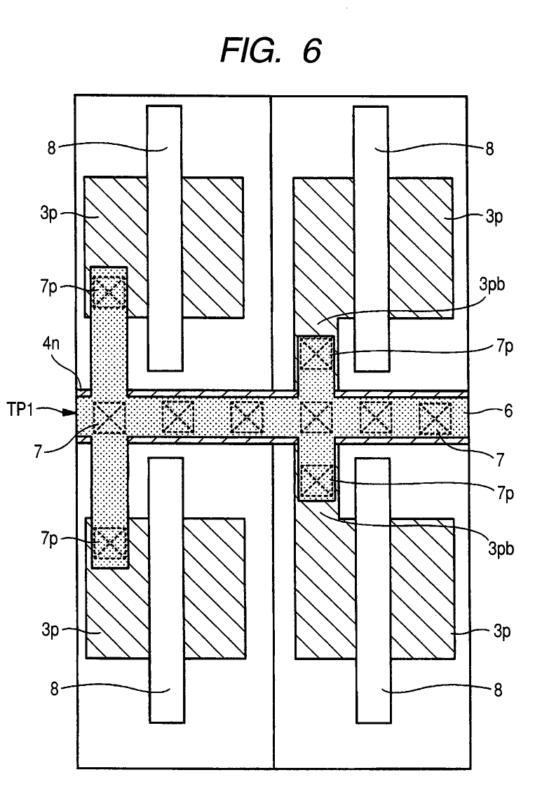

FIG. 6 is a plan view (layout pattern) of a principal part schematically showing an LSI (semiconductor device) in Embodiment 2 of the present invention. The layout pattern of the LSI in this Embodiment 2 is, as shown in FIG. 6, a combination of the layout pattern of the present invention described in the above Embodiment 1 and the layout pattern studied in the Embodiment 1. Furthermore, even if the layout pattern of the present invention and the studied layout pattern are arranged vertically or horizontally, the boundary condition thereof will not be added in particular.

By applying the present invention to the standard cell this way, the layout pattern can be given a degree of freedom.

### Embodiment 3

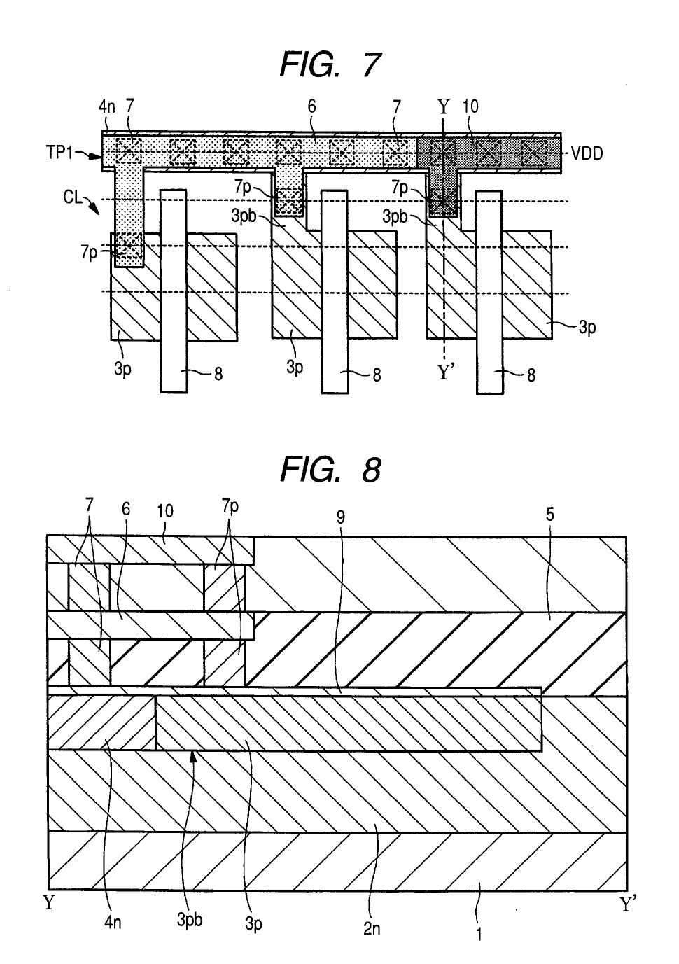

FIG. 7 is a plan view (layout pattern) of a principal part schematically showing an LSI (semiconductor device) in Embodiment 3 of the present invention, and FIG. 8 is a cross sectional view along a Y-Y′ line of FIG. 7. While the above Embodiment 1 shows the case where the power supply VDD is supplied from the first-layer wiring layer 6, this Embodiment 3 shows the case where the power supply VDD is supplied from the second-layer wiring layer 10. Even in the case where the second-layer wiring layer 10 is used for the power supply VDD, the same effect as that of the above Embodiment 1 can be obtained.

### Embodiment 4

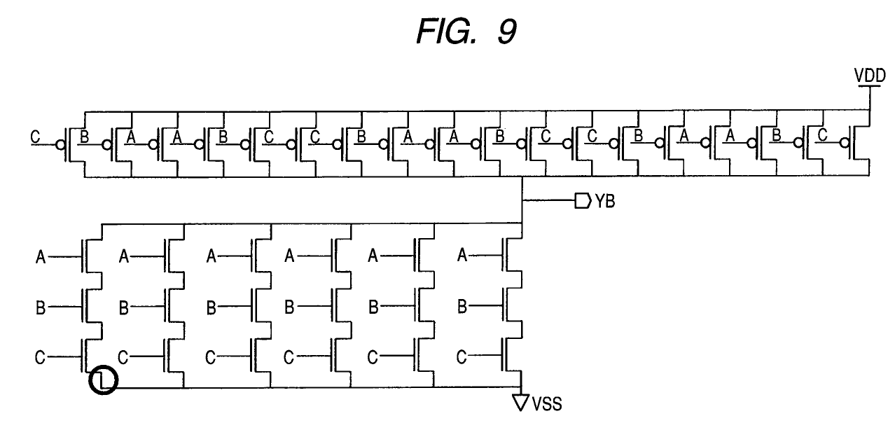

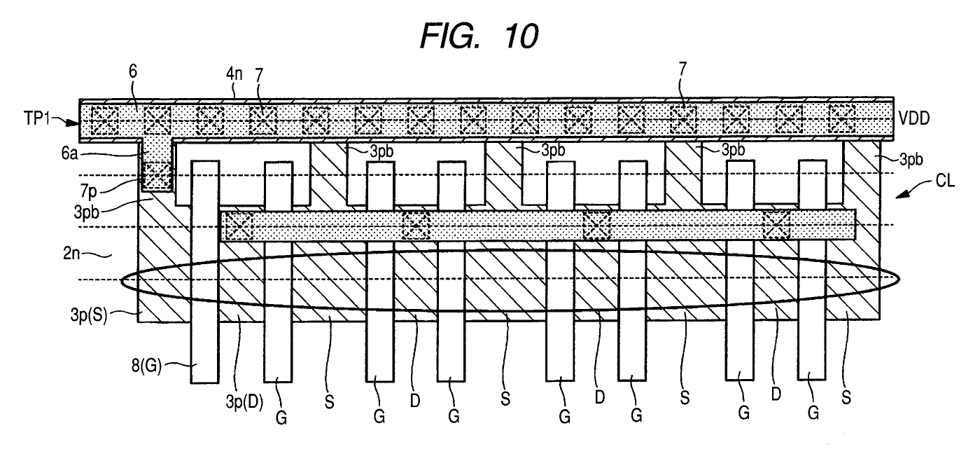

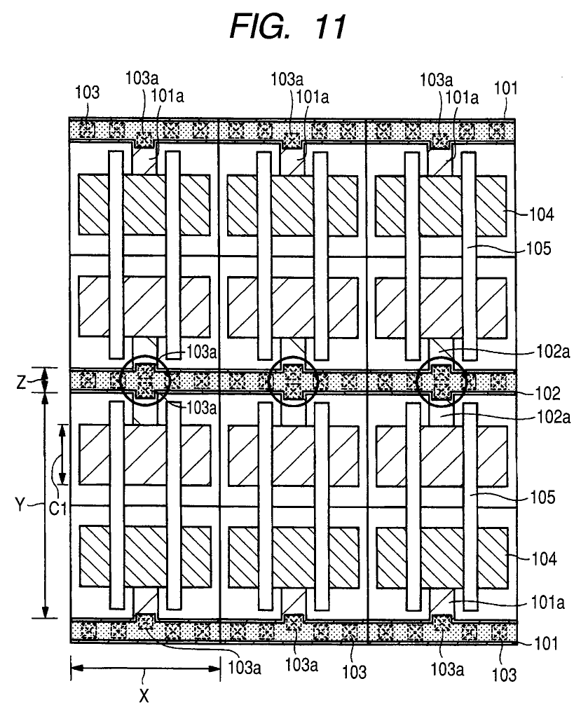

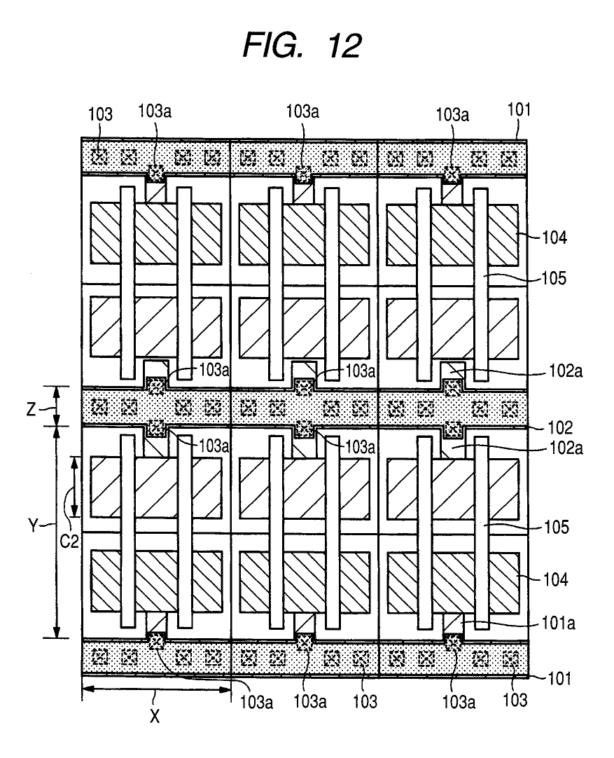

FIG. 9 is a circuit diagram of an LSI (semiconductor device) in Embodiment 4 of the present invention, and FIG. 10 is a plan view (layout pattern) of a principal part schematically showing the LSI in Embodiment 4 of the present invention. In this Embodiment 4, the LSI using redundancy by coupling MIS transistors in parallel is described.

The circuit shown in FIG. 9 is a NAND circuit with three inputs A, B, and C and one output YB. As shown in FIG. 9, by coupling the MIS transistors in parallel, a high driving power can be achieved. Relative to the driving power of one MIS transistor, a parallel connection of two MIS transistors would produce two times the driving power, a parallel connection of three MIS transistors would produce three times the driving power, and a parallel connection of n MIS transistors would produce n times the driving power.

As shown in FIG. 10, even the LSI of this Embodiment 4 is configured similar to that of Embodiment 1 described above. For example, the LSI including the standard cell CL comprises: the substrate 1; the n-type well 2n provided in the major side of the substrate 1; the p⁺-type diffusion layer 3p provided in the n-type well 2n; and the n⁺-type diffusion layer 4n provided in the n-type well 2n. This LSI further comprises: the wiring layer 6 provided in an upper layer of the substrate 1 and supplying an electric potential to the standard cell CL; the contact 7p provided above the p⁺-type diffusion layer 3p and electrically coupled to the wiring layer 6; and the contact 7 provided above the n⁺-type diffusion layer 4n and electrically coupled to the wiring layer 6. Here, this p⁺-type diffusion layer 3p constitutes the standard cell CL, the n⁺-type diffusion layer 4n constitutes the tap TP1 for supplying the electric potential of the n-type well 2n, a part of the p⁺-type diffusion layer 3p (BD part 3pb) is in contact with the n⁺-type diffusion layer 4n, and the contact 7a is provided above the BD part 3pb.

Moreover, the standard cell CL comprises a MIS transistor, the source S thereof comprises the p⁺-type diffusion layers 3p, the drain D thereof comprises the p⁺-type diffusion layers 3p which is the counterpart of the source S provided in the n-type well 2n, and the gate G thereof comprises the gate 8 provided via a gate insulating film (not illustrated) between the source S/drain D. As shown in FIG. 10, in a plurality of MIS transistors, the p⁺-type diffusion layers 3p constituting the mutual drains D are electrically coupled to each other and provided along the tap TP1 (n⁺-type diffusion layer 4n) that extends in a predetermined direction of the substrate in-plane.

Among the plurality of MIS transistors, in an MIS transistor of a region indicated by a portion enclosed by a circle in FIG. 9, the BD part 3pb (p⁺-type diffusion layer 3p) is electrically coupled to the wiring layer 6a via the contact 7a. Over the BD part 3pb of the other MIS transistors, the contact 7a is not provided, and through the metal silicide film provided so as to cover the p⁺-type diffusion layer 3p and the n⁺-type diffusion layer 4n, the electric potential of the power supply VDD will be supplied from the n⁺-type diffusion layer 4n to the p⁺-type diffusion layer 3p. Since this case requires only single portion where the wiring layer 6a is extended to over the BD part 3pb, the wiring layer 6a does not need to be extended to over the other BD parts 3pb. Accordingly, wirings can be arranged in the regions over the other BD parts 3pb for other purpose, so that the degree of freedom of the wiring layout can be improved.

Even in the LSI using redundancy by coupling the MIS transistors in parallel, the region of the portion enclosed by a circle illustrated in FIG. 10 can be effectively used within the cell forming region by applying the present invention, so that the area of the cell forming region can be reduced. Moreover, by reducing the area of the cell forming region, high integration of the semiconductor device can be achieved.

As described above, although the present invention made by the present inventor has been described specifically based on the embodiments, it is obvious that the present invention is not limited to the above embodiments and various modifications may be made without departing from the scope thereof.

For example, in the embodiments described above, although the case where the present invention is applied to the first-layer wiring layer or the second-layer wiring layer has been described, the present invention can be also applied to a multi-layer wiring layer.

The present invention is effective in semiconductor devices, particularly in LSIs, and is to be widely used in the manufacturing industries of standard cell type semiconductor devices.

What is claimed is:

1. A semiconductor device including a standard cell, comprising: a semiconductor substrate; a first conductive type well provided in a major side of the semiconductor substrate; a first diffusion layer of a second conductive type opposite to the first conductive type provided in the well; a second diffusion layer of the first conductive type provided in the well; a wiring layer provided in an upper layer of the semiconductor substrate and supplying an electric potential to the standard cell; a first contact provided above the first diffusion layer and electrically coupled to the wiring layer; and a second contact provided above the second diffusion layer and electrically coupled to the wiring layer, wherein:
the first diffusion layer constitutes the standard cell; the second diffusion layer forms a tap for supplying an electric potential of the well; a part of the first diffusion layer is in contact with the second diffusion layer; and the first contact is provided above the part of the first diffusion layer.

2. The semiconductor device according to claim 1, wherein: the semiconductor substrate is composed of silicon; a metal silicide film covering the first diffusion layer and the second diffusion layer is provided; the first contact is provided above the first diffusion layer via the metal silicide film; and the second contact is provided above the second diffusion layer via the metal silicide film.

3. The semiconductor device according to claim 1, wherein the standard cell includes an MIS transistor; and a source of the MIS transistor has the first diffusion layer.

4. The semiconductor device according to claim 1, wherein: the standard cell includes an MIS transistor; a source of the MIS transistor has the first diffusion layer; a drain of the MIS transistor has a third diffusion layer that is a counterpart of the first diffusion layer provided in the well; in a plurality of the MIS transistors, the third diffusion layers thereof are electrically coupled to one another; the MIS transistors are provided along the second diffusion layer that extends in a predetermined direction in the semiconductor substrate plane; and in at least one of the MIS transistors, the first diffusion layer is electrically coupled to the wiring layer via the first contact.

5. The semiconductor device according to claim 1, wherein a part of the first diffusion layer is present in a formation region of the standard cell.

6. A semiconductor device including a semiconductor element, comprising: a semiconductor substrate; a first conductive type well provided in a major side of the semiconductor substrate; a first diffusion layer of a second conductive type opposite to the first conductive type provided in the well; a second diffusion layer of the first conductive type provided in the well; a wiring layer provided in an upper layer of the semiconductor substrate and supplying an electric potential to the semiconductor element; a first contact provided above the first diffusion layer and electrically coupled to the wiring layer; and a second contact provided above the second diffusion layer and electrically coupled to the wiring layer, wherein: the first diffusion layer constitutes the semiconductor element; the second diffusion layer forms a tap for supplying an electric potential of the well; a part of the first diffusion layer is in contact with the second diffusion layer; and the first contact is provided above the part of the first diffusion layer.

7. The semiconductor device according to claim 6, wherein: the semiconductor substrate is composed of silicon; a metal silicide film covering the first diffusion layer and the second diffusion layer is provided; the first contact is provided above the first diffusion layer via the metal silicide film; and the second contact is provided above the second diffusion layer via the metal silicide film.

8. The semiconductor device according to claim 6, wherein the semiconductor element includes an MIS transistor; and a source of the MIS transistor has the first diffusion layer.

9. The semiconductor device according to claim 6, wherein the semiconductor element includes an MIS transistor; a source of the MIS transistor has the first diffusion layer; a drain of the MIS transistor has a third diffusion layer that is a counterpart of the first diffusion layer provided in the well; in a plurality of the MIS transistors, the third diffusion layers thereof are electrically coupled to one another; the MIS transistors are provided along the second diffusion layer that extends in a predetermined direction in the semiconductor substrate plane; and in at least one of the MIS transistors, the first diffusion layer is electrically coupled to the wiring layer via the first contact.
